(19) United States
(12) Patent Application Publication
(10) Pub. No.: US 2026/0329744 A1
(43) Pub. Date: Oct. 22, 2026

(54) A Matrix Computation Device Based on a compute-in-memory array of a flexible RRAM

(71) Applicant: INSTITUTE OF MICROELECTRONICS OF THE CHINESE ACADEMY OF SCIENCES, Beijing (CN)

(72) Inventors: Hailiang LI, Beijing (CN); Xiaofan SUN, Beijing (CN); Feng ZHANG, Beijing (CN); Di GENG, Beijing (CN); Shuaidi ZHANG, Beijing (CN); Weiye TANG, Beijing (CN)

(73) Assignee: INSTITUTE OF MICROELECTRONICS OF THE CHINESE ACADEMY OF SCIENCES, Beijing (CN)

(21) Appl. No.: 18/860,778

(22) PCT Filed: Oct. 27, 2023
(86) PCT No.: PCT/CN2023/126986

§ 371 Date: Oct. 28, 2024

(30) Foreign Application Priority Data
Aug. 15, 2023 (CN) 202311026270.5

(51) Int. Cl. G06F 12/02; G06F 17/16; H03M 1/12

(52) U.S. Cl. CPC G06F 12/0207; G06F 17/16; H03M 1/12; G06F 2212/2024

(57) ABSTRACT

A matrix computation device based on a compute-in-memory array of a flexible RRAM includes: a compute-in-memory array of a flexible RRAM configured to output the cumulative current from compute-in-memory units of individual columns to a MUX based on input of rows; the MUX configured to select one column from compute-in-memory units of columns and send cumulative current from the column to an ADC; the ADC configured to convert the cumulative current into a digital signal and send it to a subtractor; a popcount processor configured to receive input of rows, obtain the number of “1” in the input of rows and outputs it to a multiplier; the multiplier configured to multiply it by a fixed value β and sends a product result to the subtractor; the subtractor configured to subtract the product result from the digital signal to obtain a matrix multiplication addition result.

### TECHNICAL FIELD

The present application relates to the field of integrated circuit technology, and particularly relates to a matrix computation device based on a compute-in-memory array of a flexible RRAM.

### BACKGROUND ART

The current trend in artificial intelligence perception researches aims to make machines more human-like. Electronic skin can give intelligent robots the function of tactile perception, which holds great change for robotics. The development direction of tactile perception in electronic skin is to integrate sensing, storage and computation to build a sensing-storing-computing integrated architecture, which can address the power consumption bottleneck of data transfer in the von Neumann architecture and enhance overall efficiency in combination with sensing. The traditional von Neumann architecture is limited by the “memory wall bottleneck”, resulting in high power consumption and slow speed, in contrast, in-memory computing technology can achieve more efficient computational systems, reducing computational power consumption. Since convolution operations involving numerous multiplications and additions are core components of deep learning algorithms, in-memory computing and logic are highly suitable for deep neural network applications of AI and big data technologies based on AI. The BNN (Binarized Neural Networks) algorithm, while maintaining a certain level of computational accuracy, can reduce memory usage, lower power consumption and area overhead, and increase computational speed, making it very suitable for edge computing. RRAM (Resistive Random Access Memory), which is a new type of non-volatile memory, because of advantages such as simple structure, high integration, low power consumption and so on, is considered as a new device with the most possibility to break through the limitations of traditional devices and has been applied to in-memory computing.

Although there have been many achievements in the design of flexible pressure sensors, the development of flexible computing chips is still in the exploratory stage, which is crucial for creating truly flexible electronic skin. Currently, RRAM-based in-memory computing chips implement the BNN algorithm through XNOR operations based on the 2T2R structure (one compute-in-memory unit is built by 2 RRAM and 2 MOS transistors), therefore, to further enhance energy efficiency and apply it to flexible computing chips to create electronic skin, a matrix computation device based on a flexible RRAM and flexible compute-in-memory array with a 1T1R structure of IGZO TFTs is urgently needed.

### SUMMARY OF THE INVENTION

In view of the above analysis, the present application aims at providing a matrix computation device based on a compute-in-memory array of a flexible RRAM to solve the problems of large size and unsuitability for electronic skin in current compute-in-memory arrays.

In one aspect, the embodiment of the present application provides a matrix computation device based on a compute-in-memory array of a flexible RRAM, wherein the device comprises: the compute-in-memory array of the flexible RRAM, a multiplexer selector MUX, an analog-to-digital converter ADC, a popcount module, a multiplier and a subtractor;
the compute-in-memory array of the flexible RRAM is configured to output the cumulative current from compute-in-memory units of individual columns to the multiplexer selector MUX based on input of a plurality of rows;
the multiplexer selector MUX is configured to select one column from compute-in-memory units of individual columns and send the cumulative current from the compute-in-memory units of the column to the analog-to-digital converter ADC;
the analog-to-digital converter ADC is configured to convert the cumulative current outputted from the compute-in-memory array of the flexible RRAM into a digital signal and send it to the subtractor;
the popcount module is configured to receive input of a plurality of rows, obtain the number of “1” in the input of a plurality of rows and output the number of “1” to the multiplier;
the multiplier is configured to multiply the number of “1” by a fixed value β and send the product result to the subtractor;
the subtractor is configured to subtract the product result from the digital signal to obtain a result of the matrix multiplication and addition.

Further, wherein the compute-in-memory array of the flexible RRAM comprises n×m compute-in-memory units;
the word lines WL for the compute-in-memory units of each row are connected in sequence, the source lines SL for the compute-in-memory units of each column are connected in sequence, the bit lines BL for the compute-in-memory units of each column are connected in sequence, the bit lines BL are used to output the computing results of the compute-in-memory units of that column;
each of the compute-in-memory units is a 1T1R structure, including one transistor and one memory resistor.

Further, wherein the transistor is an indium gallium zinc oxide-based thin-film transistor IGZO TFT, the memory resistor is RRAM;
a gate of the indium gallium zinc oxide-based thin-film transistor IGZO TFT is connected to the word line WL for the compute-in-memory unit, a drain thereof is connected to the bit line BL for the compute-in-memory unit, a source thereof is connected to one end of the memory resistor RRAM, the other end of the memory resistor RRAM is connected to the source line SL for the compute-in-memory unit.

Further, wherein the operating modes of the compute-in-memory array of the flexible RRAM include a weight writing mode and an inference operation mode.

Further, wherein, in the weight writing mode, by controlling the connection voltage of the word lines WL, bit lines BL and source lines SL, the resistance state of the memory resistor RRAM is changed, thereby achieving weight writing.

Further, wherein, when the word line WL is connected to a high level, the bit line BL is connected to the writing voltage Vw and the source line SL is grounded, the conductance state of the memory resistor RRAM is in the low resistance state LRS, assigning 3+1 to its weight;
when the word line WL is connected to a high level, the bit line BL is grounded and the source line SL is connected to the writing voltage Vw, the conductance state of the memory resistor RRAM is in the high resistance state HRS, assigning β−1 to its weight;
when the word line WL is connected to a low level, indicating that the memory resistor RRAM is not selected, the resistance state of the memory resistor RRAM remains unchanged.

Further, the weight writing mode adopts a half-voltage method, wherein the writing voltage Vw is greater than the threshold voltage of the memory resistor RRAM, and half of the writing voltage Vw is less than the threshold voltage of the memory resistor RRAM, to ensure that the state of unselected memory resistors RRAM remains unchanged.

Further, wherein, in the inference operation mode, the bit line BL is connected to the reading voltage Vr and the source line SL is grounded, the input of the compute-in-memory unit is determined based on whether the word line WL is connected to a high or low level, the current outputted by the compute-in-memory unit is taken as the product of the input of the compute-in-memory unit and the weight of the memory resistor RRAM, the currents outputted by individual compute-in-memory units in the compute-in-memory units of each column are combined in the bit line corresponding to the compute-in-memory units of that column, so that the bit line output is the sum of the products of individual units of the compute-in-memory units of that column.

Further, wherein, when the word line WL is connected to a high level and the resistance state of the memory resistor RRAM is in the high resistance state HRS, the input of the compute-in-memory unit is 1, the output thereof is a low current I_{L}, where the value of the low current I_{L} is β−1;
when the word line WL is connected to a high level and the resistance state of the memory resistor RRAM is in the low resistance state LRS, the input of the compute-in-memory unit is 1, the output thereof is a high current I_{H}, where the value of the high current I_{H} is β+1;
when the word line WL is connected to a low level, the indium gallium zinc oxide-based thin-film transistor IGZO TFT is turned off, the compute-in-memory unit is not connected, the input of the compute-in-memory unit is 0, then the output current of the compute-in-memory unit is 0.

Further, wherein the β>1.

Compared with existing technology, the present application achieves at least one of the following beneficial effects:
1. By using a compute-in-memory array of a flexible RRAM with a 1T1R unit structure, where both the indium gallium zinc oxide-based thin-film transistor IGZO TFT and the memory resistor RRAM in the 1T1R unit structure are both flexible structures, the present application reduces the area of the compute-in-memory array by half without affecting computational accuracy comparing with the traditional 2T2R structure, further enhances energy efficiency, and its flexibility makes it more suitable for creating electronic skin.
2. The design of peripheral circuits such as the ADC, popcount module, multiplier subtractor and so on enhances the computing accuracy of the matrix computation.

In the present application, the above technical solutions can be combined, to implement more preferred combined solutions. Other features and advantages of the present application will be described in the subsequent specification, and part of the advantages can become apparent from the specification, or be understood through the implementation of the present application. The objects and other advantages of the present application can be implemented and obtained from the contents particularly illustrated in the specification and the drawings.

### DESCRIPTION OF THE DRAWINGS

The drawings are merely for the purpose of illustrating the particular embodiments, and are not considered as limitation to the present application. Throughout the drawings, the same reference signs denote the same elements.

FIG. 1 is a circuit structural diagram of the compute-in-memory array of the flexible RRAM;

FIG. 2 is a computational coding table of the compute-in-memory array of the RRAM based on the 1T1R structure;

FIG. 3 is an overall circuit block diagram of the compute-in-memory array of the RRAM.

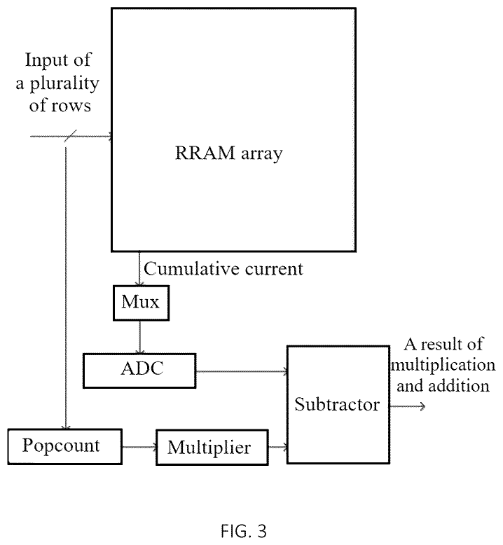

### DETAILED EMBODIMENTS

The preferable embodiments of the present application will be particularly described below by referring to the drawings. The drawings form part of the present application, are used to explain the principle of the present application together with the embodiments of the present application, and are not limiting the scope of the present application.

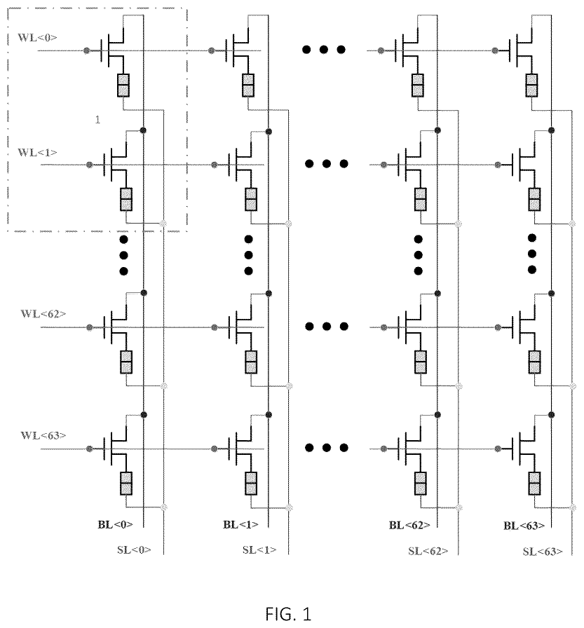

A particular embodiment of the present application discloses a matrix computation device based on a compute-in-memory array of a flexible RRAM, as shown in FIG. 1. The device comprises: the compute-in-memory array of the flexible RRAM, a multiplexer selector MUX, an analog-to-digital converter ADC, a popcount module, a multiplier and a subtractor;
the compute-in-memory array of the flexible RRAM is configured to output the cumulative current of compute-in-memory units of individual columns to the multiplexer selector MUX based on input of a plurality of rows;
the multiplexer selector MUX is configured to select one column from the compute-in-memory units of individual columns and send the cumulative current from the compute-in-memory units of that column to the analog-to-digital converter ADC;
the analog-to-digital converter ADC is configured to convert the cumulative current outputted from the compute-in-memory array of the flexible RRAM into a digital signal and send it to the subtractor;
the popcount module is configured to receive input of a plurality of rows, obtain the number of “1” in the input of a plurality of rows and output the number of “1” to the multiplier;
the multiplier is configured to multiply the number of “1” by a fixed value β and send the product result to the subtractor;
the subtractor is configured to subtract the product result from the digital signal to obtain a result of the matrix multiplication and addition.

Specifically, the function of the multiplier is to multiply the input by a fixed β value, wherein the fixed β value is determined by the performance of the compute-in-memory array of the RRAM,

$$β = \frac{{I}_{H} + {I}_{L}}{{I}_{H} - {I}_{L}} .$$

For example, if the matrix multiplication is [1,0,1,0,1]*[+1,+1,−1,−1,−1], that is, the input of a plurality of rows is [1,0,1,0,1], the weight of a certain column in the compute-in-memory array of RRAM is [+1,+1,−1,−1,−1], the result of the matrix multiplication and addition is −1, input of a plurality of rows corresponding to the compute-in-memory array of the RRAM are 10101, the resistance states inputted to the corresponding RRAM units are β+1, β+1, β−1, β−1, β−1 respectively. Then the accumulated current outputted from that column in the compute-in-memory array of the RRAM is inputted to the multiplexer selector, the multiplexer selector selectively is output the accumulated current from that column in the compute-in-memory array of the RRAM to the ADC for conversion. The ADC outputs a current digital signal with a magnitude of 3β−1 to the subtractor. The output of the popcount module is 3, the output of the multiplier is 3β, then the output of the subtractor is −1, showing that this solution is identical to the original result of the matrix multiplication and addition.

Further, the compute-in-memory array of the flexible RRAM comprises n×m compute-in-memory units;
the word lines WL for the compute-in-memory units of each row are connected in sequence, the source lines SL for the compute-in-memory units of each column are connected in sequence, the bit lines BL for the compute-in-memory units of each column are connected in sequence, the bit lines BL are used to output the computing results of the compute-in-memory units of that column;
each of the compute-in-memory units is a 1T1R structure, including one transistor and one memory resistor.

Further, the transistor is an indium gallium zinc oxide-based thin-film transistor IGZO TFT, the memory resistor is RRAM;
a gate of the indium gallium zinc oxide-based thin-film transistor IGZO TFT is connected to the word line WL for the compute-in-memory unit, the drain thereof is connected to the bit line BL for the compute-in-memory unit, the source thereof is connected to one end of the memory resistor RRAM, the other end of the RRAM is connected to the source line SL for the compute-in-memory unit.

Further, the operating modes of the compute-in-memory array of the flexible RRAM include a weight writing mode and an inference operation mode.

Specifically, when the bit line BL or source line SL is connected to the writing voltage Vw, the working mode of the compute-in-memory array of the flexible RRAM is the weight writing mode. When the bit line BL is connected to the reading voltage Vr, the working mode of the compute-in-memory array of the flexible RRAM is the inference operation mode.

Specifically, by controlling the input voltages of the word line WL, the bit line BL and the source line SL connected to the array through peripheral fpga, that is, the word line WL connects to a high or low level, thereby controlling the on/off state of the transistor and selecting whether the current compute-in-memory unit is activated or not. When the word line WL is connected to a high level, the transistor is on, meaning the compute-in-memory unit is activated. When the word line WL is connected to a low level, the transistor is off, meaning the compute-in-memory unit is not activated.

Further, in the weight writing mode, by controlling the connection voltage of the word line WL, bit line BL and source line SL, the resistance state of the memory resistor RRAM is changed, thereby achieving weight writing.

Further, when the word line WL is connected to a high level, the bit line BL is connected to the writing voltage Vw and the source line SL is grounded, the conductance state of the memory resistor RRAM is in the low resistance state LRS, assigning β+1 to its weight;
when the word line WL is connected to a high level, the bit line BL is grounded and the source line SL is connected to the writing voltage Vw, the conductance state of the memory resistor RRAM is in the high resistance state HRS, assigning β−1 to its weight;
when the word line WL is connected to a low level, indicating that the memory resistor RRAM is not selected, the resistance state of the memory resistor RRAM remains unchanged.

In the weight writing mode, the high or low resistance state of the RRAM is set by controlling the writing voltage Vw of the compute-in-memory unit and the on/off state of the transistor, thus completing the deployment of weights in the RRAM array. The outputs of the source line SL and the bit line BL are grounded or connected to the writing voltage, and the word line WL controls the on/off state of the transistor to control the weight writing of the RRAM in the compute-in-memory unit. For example, when the word line WL<0> is connected to a high level, the source line SL is grounded, the bit line BL is connected to the write voltage, then the RRAM is programmed to a low resistance state.

Specifically, in the weight writing mode and the inference operation mode, because the memory resistor RRAM is a non-volatile component, once the resistance state of the RRAM is set in the weight writing mode, the resistance state of the memory resistor RRAM remains fixed and does not change unless a new programming voltage is applied to the word line WL, the bit line BL and the source line SL.

Further, the weight writing mode adopts a half-voltage method, wherein the writing voltage Vw is greater than the threshold voltage of the memory resistor RRAM, and half of the writing voltage Vw is less than the threshold voltage of the memory resistor RRAM, to ensure that the state of unselected memory resistors RRAM remains unchanged.

Further, in the inference operation mode, the bit line BL is connected to the reading voltage Vr and the source line SL is grounded, the input of the compute-in-memory unit is determined based on whether the word line WL is connected to high or a low level, the current outputted by the compute-in-memory unit is taken as the product of the input of the compute-in-memory unit and the weight of the memory resistor RRAM, the currents outputted by each compute-in-memory unit in the compute-in-memory units of each column are combined in the bit line corresponding to the compute-in-memory units of that column, so that output of the bit line is the sum of the products of individual units of the compute-in-memory units of that column.

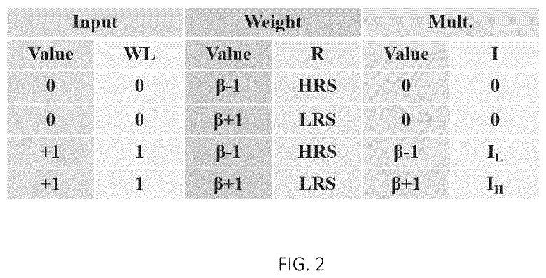

Further, as shown in FIG. 2, when the word line WL is connected to a high level and the resistance state of the memory resistor RRAM is in the high resistance state HRS, the input of the compute-in-memory unit is 1, the output thereof is a low current I_{L}, where the value of the low current I_{L} is β−1;
when the word line WL is connected to a high level and the resistance state of the memory resistor RRAM is in the low resistance state LRS, the input of the compute-in-memory unit is 1, the output is a high current I_{H}, where the value of the high current I_{H} is β+1;
when the word line WL is connected to a low level, the indium gallium zinc oxide-based thin-film transistor IGZO TFT is turned off, the compute-in-memory unit is not connected, the input of the compute-in-memory unit is 0, then the output current of the compute-in-memory unit is 0.

In the inference operation mode, the entire RRAM array can achieve the function of matrix multiplication and addition computation. By controlling the on/off state of the TFT transistor through the word line WL, the input is realized: when the word line WL is connected to a high level, the TFT transistor is on, meaning the compute-in-memory unit is activated and the input is 1; when the word line WL is connected to a low level, the transistor is off, meaning the unit is not connected and the input is 0. The source line SL is grounded, the bit line BL is connected to the reading voltage Vr and receives the corresponding accumulated current, which is the multiplication and addition result. The high or low resistance state of the RRAM via programming represents the weight distribution. When a bit line BL of the RRAM array is selected, it will generate a current I_{H} or I_{L} based on the high or low resistance state. For example, when the word line WL<0> is connected to a high level, and the RRAM is in a high resistance state, the compute-in-memory unit generates a reference current I_{L}, representing the computation result of the unit is β−1 (β>1). In the similar way of computing the compute-in-memory units of the whole column, the accumulated current obtained at the output bit line BL represents the result of the matrix multiplication and addition of the compute-in-memory units in that column. Thus, a compute-in-memory unit can be formed using only one TFT transistor and one RRAM, thereby forming a compute-in-memory array.

This solution reduces the area of the compute-in-memory array by half without affecting computational accuracy and improves the overall energy efficiency of the computational chip when combined with peripheral circuits. Moreover, this solution uses flexible IGZO TFTs and flexible RRAM as basic components to construct a completely flexible compute-in-memory array. Combined with peripheral circuits, it builds a matrix computation device based on the compute-in-memory array of the flexible RRAM, providing a solid foundation for the subsequent manufacture of completed electronic skins. Furthermore, it provides a binary multiplication and addition calculation method based on compute-in-memory array of the RRAM, providing a good foundation for the hardware circuit implementation of intelligent algorithms in the future.

Further, the β>1.

Specifically, the present application corresponds to a modified binary computation. The input of the word line WL controls whether the transistor is on or off. In the weight writing mode, the high and low resistance states of the memory resistor RRAM are determined by controlling the voltages applied to the bit line BL and source line SL. Since both the high and low resistance states are actually positive values, the low resistance state and high resistance state are encoded as β+1 and β−1 respectively. In the inference operation mode, the output also changes accordingly, being binary high current and low current too.

Further, the size of the compute-in-memory array of the flexible RRAM is 64×64, with a total capacity of 4 Kb.

Compared with existing technology, a matrix computation device based on the compute-in-memory array of the flexible RRAM provided by the embodiment uses the compute-in-memory array of the flexible RRAM with a 1T1R unit structure. The indium gallium zinc oxide-based thin-film transistor IGZO TFT and the memory resistor RRAM in the 1T1R unit structure are both flexible. The present application reduces the area of the compute-in-memory array by half without affecting computational accuracy comparing with the traditional 2T2R structure, further enhances energy efficiency combined with peripheral circuits. Its flexibility makes it more suitable for creating electronic skin. The design of peripheral circuits such as the ADC, popcount module, multiplier, subtractor and so on enhances the computing accuracy of the matrix computation. The present application provides a binary matrix multiplication and addition calculation method based on the compute-in-memory array of the RRAM, providing a good foundation for the hardware circuit implementation of intelligent algorithms in the future.

A person skilled in the art can understand that all or part of the process of implementing the methods of the above embodiments may be implemented by related hardware according to an instruction from a computer program, and the program may be stored in a computer-readable storage medium, wherein the computer-readable storage medium is a magnetic disc, an optical disc, a read-only memory, a random access memory and so on.

The above are merely preferable particular embodiments of the present application, and the protection scope of the present application is not limited thereto. All of the variations or substitutions that a person skilled in the art can easily envisage within the technical scope disclosed by the present application should fall within the protection scope of the present application.

1. A matrix computation device based on a compute-in-memory array of a flexible RRAM, wherein the device comprises: the compute-in-memory array of the flexible RRAM, a multiplexer selector MUX, an analog-to-digital converter ADC, a popcount processor, a multiplier and a subtractor;
the compute-in-memory array of the flexible RRAM configured to output cumulative current from compute-in-memory units of individual columns to the multiplexer selector MUX based on input of a plurality of rows;
the multiplexer selector MUX configured to select one column from the compute-in-memory units of the individual columns and sends the cumulative current from the compute-in-memory units of the column to the analog-to-digital converter ADC;
the analog-to-digital converter ADC configured to convert the cumulative current outputted from the compute-in-memory array of the flexible RRAM into a digital signal and sends it to the subtractor;
the popcount processor configured to receive input of a plurality of rows, obtains the number of “1” in the input of a plurality of rows and outputs the number of “1” to the multiplier;
the multiplier configured to multiply the number of “1” by a fixed value β and sends a product result to the subtractor;
the subtractor configured to subtract the product result from the digital signal to obtain a result of the matrix multiplication and addition.

2. The matrix computation device based on the compute-in-memory array of the flexible RRAM according to claim 1, wherein the compute-in-memory array of the flexible RRAM comprises n×m compute-in-memory units;
word lines WL for the compute-in-memory units of each row are connected in sequence, source lines SL for the compute-in-memory units of each column are connected in sequence, bit lines BL for the compute-in-memory units of each column are connected in sequence, the bit lines BL are used to output the computing results of the compute-in-memory units of that column;
each of the compute-in-memory units is a 1T1R structure, including one transistor and one memory resistor.

3. The matrix computation device based on the compute-in-memory array of the flexible RRAM according to claim 2, wherein the transistor is an indium gallium zinc oxide-based thin-film transistor IGZO TFT, the memory resistor is a RRAM;
a gate of the indium gallium zinc oxide-based thin-film transistor IGZO TFT is connected to the word line WL for the compute-in-memory unit, a drain thereof is connected to the bit line BL for the compute-in-memory unit, a source thereof is connected to one end of the memory resistor RRAM, the other end of the memory resistor RRAM is connected to the source line SL for the compute-in-memory unit.

4. The matrix computation device based on the compute-in-memory array of the flexible RRAM according to claim 3, wherein the operating modes of the compute-in-memory array of the flexible RRAM comprise a weight writing mode and an inference operation mode.

5. The matrix computation device based on the compute-in-memory array of the flexible RRAM according to claim 4, wherein, in the weight writing mode, by controlling the connection voltage of the word lines WL, bit lines BL and source lines SL, the resistance state of the memory resistor RRAM is changed, thereby achieving weight writing.

6. The matrix computation device based on the compute-in-memory array of the flexible RRAM according to claim 5, wherein, when the word line WL is connected to a high level, the bit line BL is connected to the writing voltage Vw and the source line SL is grounded, the conductance state of the memory resistor RRAM is in the low resistance state LRS, assigning β+1 to its weight;
when the word line WL is connected to a high level, the bit line BL is grounded and the source line SL is connected to the writing voltage Vw, the conductance state of the memory resistor RRAM is in the high resistance state HRS, assigning β−1 to its weight;
when the word line WL is connected to a low level, indicating that the memory resistor RRAM is not selected, the resistance state of the memory resistor RRAM remains unchanged.

7. The matrix computation device based on the compute-in-memory array of the flexible RRAM according to claim 6, the weight writing mode adopts a half-voltage method, wherein the writing voltage Vw is greater than the threshold voltage of the memory resistor RRAM, and half of the writing voltage Vw is less than the threshold voltage of the memory resistor RRAM, to ensure that the state of unselected memory resistors RRAM remains unchanged.

8. The matrix computation device based on the compute-in-memory array of the flexible RRAM according to claim 7, wherein, in the inference operation mode, the bit line BL is connected to the reading voltage Vr and the source line SL is grounded, the input of the compute-in-memory unit is determined based on whether the word line WL is connected to a high or low level, the current outputted by the compute-in-memory unit is taken as the product of the input of the compute-in-memory unit and the weight of the memory resistor RRAM, the currents outputted by individual compute-in-memory units in the compute-in-memory units of each column are combined in the bit line corresponding to the compute-in-memory units of the column, so that the bit line output is the sum of the products of individual units of the compute-in-memory units of that column.

9. The matrix computation device based on the compute-in-memory array of the flexible RRAM according to claim 8, wherein, when the word line WL is connected to a high level and the resistance state of the memory resistor RRAM is in the high resistance state HRS, the input of the compute-in-memory unit is 1, the output thereof is a low current IL, where the value of the low current IL is β−1;
when the word line WL is connected to a high level and the resistance state of the memory resistor RRAM is in the low resistance state LRS, the input of the compute-in-memory unit is 1, the output thereof is a high current IH, where the value of the high current IH is β+1;
when the word line WL is connected to a low level, the indium gallium zinc oxide-based thin-film transistor IGZO TFT is turned off, the compute-in-memory unit is not connected, the input of the compute-in-memory unit is 0, then the output current of the compute-in-memory unit is 0.

10. The matrix computation device based on the compute-in-memory array of the flexible RRAM according to claim 9, wherein the >1.
